(19) United States
(12) Patent Application Publication
(10) Pub. No.: US 2025/0087964 A1
(43) Pub. Date: Mar. 13, 2025

(54) MANUFACTURING METHOD OF MOUNTING SUBSTRATE, MOUNTING SUBSTRATE, AND LIGHT-EMITTING MODULE

(71) Applicant: NICHIA CORPORATION, Anan-shi (JP)

(72) Inventors: Yosuke NODA, Tokushima-shi (JP); Masakazu SAKAMOTO, Tokushima-shi (JP); Miwako KAZUNOBU, Komatsushima-shi (JP)

(21) Appl. No.: 18/830,565

(22) Filed: Sep. 10, 2024

(30) Foreign Application Priority Data
Sep. 12, 2023 (JP) 2023-147651

(51) Int. Cl. H01S 5/02; H01S 5/024

(52) U.S. Cl. CPC H01S 5/0215; H01S 5/02469

(57) ABSTRACT

A manufacturing method of a mounting substrate includes: preparing a substrate including a mounting portion having a mounting surface, a first protruding portion having a first upper surface located above the mounting surface, and a second protruding portion having a second upper surface located above the mounting surface, the mounting surface being located between the first and second upper surfaces in a top view; disposing the substrate on a support member having a support surface such that the first and second upper surfaces face the support surface; and providing first and second through holes from a lower surface side toward an upper surface side of the substrate at first and second positions between which the mounting surface is interposed in the top view, the first and second positions not being located between the first upper surface and the mounting surface nor between the second upper surface and the mounting surface.

### CROSS-REFERENCE TO RELATED APPLICATIONS

This application claims priority to Japanese Patent Application No. 2023-147651, filed on Sep. 12, 2023, the disclosure of which is hereby incorporated herein by reference in its entirety.

### BACKGROUND

The present invention relates to a manufacturing method of a mounting substrate, a mounting substrate, and a light-emitting module.

The international publication WO 2014/41936 discloses an embodiment in which a semiconductor device is mounted on a heat dissipation member. The heat dissipation member suppresses an increase in temperature of the semiconductor device.

### SUMMARY

One aspect of the present disclosure is directed to solve a problem of implementing a mounting substrate having an excellent heat dissipation effect on which a light-emitting device is mounted is disclosed.

Alternatively, another aspect of the present disclosure is directed to solve a problem of implementing a mounting substrate in which a shape of warp is controlled is disclosed.

Alternatively, another aspect of the present disclosure is directed to solve a problem of implementing a mounting substrate in which variation in heat dissipation effect is suppressed is disclosed.

The present disclosure may also be directed to solve a plurality of the problems of the above-described problems.

A manufacturing method of a mounting substrate disclosed in an embodiment includes: preparing a substrate including a mounting portion having a mounting surface, a first protruding portion having a first upper surface located above the mounting surface, and a second protruding portion having a second upper surface located above the mounting surface, the mounting surface being located between the first upper surface and the second upper surface in a top view; disposing the substrate on a support member having a support surface such that the first upper surface and the second upper surface face the support surface; and providing a first through hole and a second through hole from a lower surface side toward an upper surface side of the substrate at a first position and a second position between which the mounting surface is interposed in the top view, the first position and the second position not being located between the first upper surface and the mounting surface nor between the second upper surface and the mounting surface.

A mounting substrate disclosed in an embodiment includes a lower surface, a mounting portion having a mounting surface, a first protruding portion having a first upper surface located above the mounting surface, a second protruding portion having a second upper surface located above the mounting surface, and an outer peripheral portion defining a first through hole and a second through hole, the outer peripheral portion being located outside the mounting portion. The mounting surface is located between the first upper surface and the second upper surface and between the first through hole and the second through hole in a top view. The first through hole and the second through hole are not provided between the first upper surface and the mounting surface nor between the second upper surface and the mounting surface in the top view. The lower surface is warped with a shape in which a point located directly below the mounting surface is located below a virtual line segment connecting a point located directly below the first upper surface and a point located directly below the second upper surface on the lower surface.

A light-emitting module disclosed in an embodiment includes the above-described mounting substrate and a light-emitting device mounted on the mounting surface.

At least one of one or more embodiments disclosed in the present disclosure allows the mounting substrate having an excellent heat dissipation effect to be achieved.

### BRIEF DESCRIPTION OF DRAWINGS

FIG. 1 is a top view of a light-emitting module according to an embodiment.

FIG. 2 is a perspective view of the light-emitting module according to an embodiment in a state of not being fixed to a heat sink.

FIG. 3 is a perspective view of a light-emitting device according to an embodiment.

FIG. 4 is a side view of the light-emitting device according to an embodiment.

FIG. 5 is a cross-sectional view of the light-emitting device taken along a cross-sectional line V-V in FIG. 3.

FIG. 6 is a perspective view illustrating components disposed inside the light-emitting device according to an embodiment.

FIG. 7 is a top view illustrating components disposed inside the light-emitting device according to an embodiment.

FIG. 8 is a perspective view of a package according to an embodiment.

FIG. 9 is a cross-sectional view of the package taken along a cross-sectional line IX-IX in FIG. 8.

FIG. 10 is a top view of a base according to an embodiment.

FIG. 11 is a bottom view of the base according to an embodiment.

FIG. 12 is a cross-sectional view of the base taken along a cross-sectional line XII-XII in FIG. 10.

FIG. 13 is a top view of a state in which a light-emitting element and a protective element are disposed on a submount.

FIG. 14 is a side view of the state in which the light-emitting element and the protective element are disposed on the submount.

FIG. 15 is a top view of a wiring substrate according to the embodiment.

FIG. 16 is a cross-sectional view of the wiring substrate taken along a cross-sectional line XVI-XVI in FIG. 15.

FIG. 17A is a cross-sectional view for describing a first step in a manufacturing method of the wiring substrate according to an embodiment.

FIG. 17B is a cross-sectional view for describing a second step in the manufacturing method of the wiring substrate according to an embodiment.

FIG. 17C is a cross-sectional view for describing a third step in the manufacturing method of the wiring substrate according to an embodiment.

FIG. 18A is a cross-sectional view for describing a fourth step in the manufacturing method of the substrate according to an embodiment.

FIG. 18B is a cross-sectional view for describing a fifth step in the manufacturing method of the substrate according to an embodiment.

FIG. 18C is a cross-sectional view for describing a sixth step in the manufacturing method of the substrate according to an embodiment.

### DETAILED DESCRIPTION

In the present specification or the claims, polygons such as triangles and quadrangles, including shapes in which the corners of the polygon are rounded, beveled, chamfered, or coved, are referred to as polygons. A shape obtained by processing not only the corners (ends of a side) but also an intermediate portion of the side is similarly referred to as a polygon. That is, a shape that is partially processed while remaining a polygon shape as a base is included in the interpretation of “polygon” described in the present specification and the claims.

The same applies not only to polygons but also to words representing specific shapes such as trapezoids, circles, protrusions, and recesses. The same applies when dealing with each side forming that shape. That is, even if processing is performed on a corner or an intermediate portion of a certain side, the interpretation of “side” includes the processed portion. When a “polygon” or “side” not partially processed is to be distinguished from a processed shape, “exact” will be added to the description as in, for example, “exact quadrangle”.

Further, in the present specification or the claims, descriptions such as upper and lower (upward/downward), left and right, surface and reverse, front and back (forward/backward), and near and far are used merely to describe the relative relationship of positions, orientations, and directions, and the expressions are not necessarily match an actual relationship at the time of use.

In the drawings, directions such as an X direction, a Y direction, and a Z direction may be indicated by using arrows. The directions of the arrows are consistent across multiple drawings of the same embodiment. In addition, in the drawings, the directions of the arrows marked with X, Y, and Z are the positive directions, and the opposite directions are the negative directions. For example, the direction marked with X at the tip of the arrow is the X direction and the positive direction. In the present specification, the direction that is the X direction and is the positive direction will be referred to as the “positive direction of X” and the direction opposite to this will be referred to as the “negative direction of X”. The term “X direction” includes both the positive direction and the negative direction. The same applies to the Y direction and the Z direction. The directional terms such as “upper,” “lower,” “top,” “bottom,” “above,” “over,” “below,” etc. as used herein refer to the direction when the device is oriented so that the positive direction of Z is the upward direction.

In addition, in the present specification, when a certain object is specified as “one or more” and the object is described, an embodiment in which the object is one and an embodiment in which the object is plural are collectively described. Thus, a description specified as “one or more” supports every case of an embodiment including one or more objects, an embodiment including at least one object, and an embodiment including a plurality of objects.

In addition, in the present specification, the description illustrating “one or each” object is a description summarizing a description of one object in an embodiment including the one object, a description of one object in an embodiment including a plurality of objects, and a description of each of a plurality of objects in an embodiment including the plurality of objects. Thus, the description illustrating “one or each” object supports every case of an embodiment including one object in which the one object satisfies the described content, an embodiment including a plurality of objects in which, among these objects, at least one of the objects satisfies the described content, and an embodiment including a plurality of objects in which each of these plurality of objects satisfies the described content, and an embodiment including one or more objects in which all of the objects satisfy the described content.

The term “member” or “portion” may be used to describe, for example, a component in the present specification. The term “member” refers to an object physically treated alone. The object physically treated alone can be an object treated as one part in a manufacturing process. Meanwhile, the term “portion” refers to an object that need not be physically treated alone. For example, the term “portion” is used when part of one member is partially considered, or a plurality of members are collectively considered as one object.

The distinction between “member” and “portion” described above does not indicate an intention to consciously limit the scope of right in interpretation of the doctrine of equivalents. That is, even when a component described as “member” is present in the claims, this does not mean that the applicant recognizes that physically treating the component alone is essential in the application of the present invention.

In the present specification or the claims, when a plurality of components are present and these components are to be indicated separately, the components may be distinguished by adding the terms “first” and “second” at the beginning of the names of the components. Objects to be distinguished may differ between the present specification and the claims. Thus, even when a component in the claims is given the same term as that in the present specification, the object identified by that component is not the same across the present specification and the claims in some cases.

For example, when components distinguished by being termed “first”, “second”, and “third” are present in the present specification, and when components given the terms “first” and “third” in the present specification are described in the claims, these components may be distinguished by being denoted as “first” and “second” in the claims for ease of understanding. In this case, the components denoted as “first” and “second” in the claims refer to the components termed “first” and “third” in the present specification, respectively. This rule applies to not only components but also other objects in a reasonable and flexible manner.

Embodiments for implementing the present invention will be described below. Specific embodiments for implementing the present invention will be described below with reference to the drawings. Embodiments for implementing the present invention are not limited to the specific embodiments. That is, the embodiments illustrated by the drawings are not the only form in which the present invention is realized. Sizes and positional relationships of members illustrated in each of the drawings may sometimes be exaggerated in order to facilitate understanding.

### Embodiment

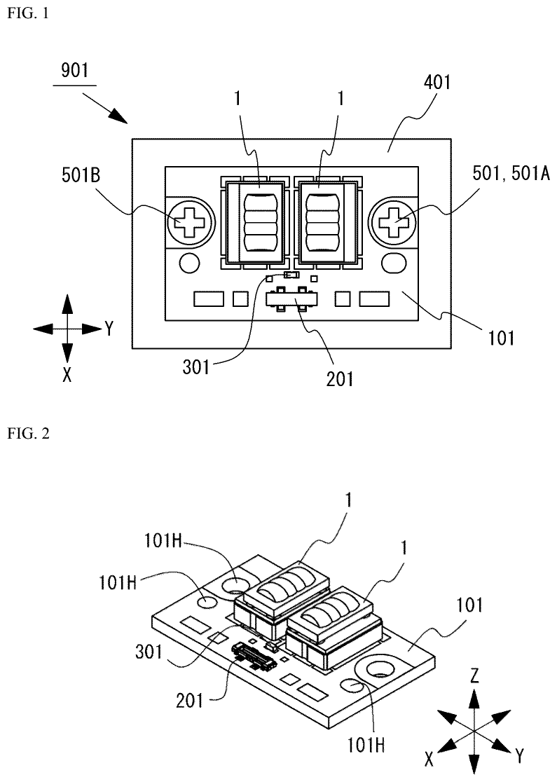

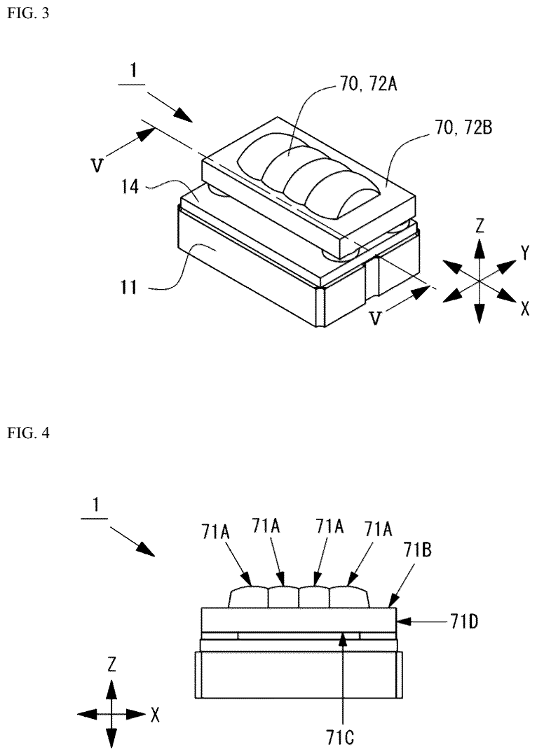

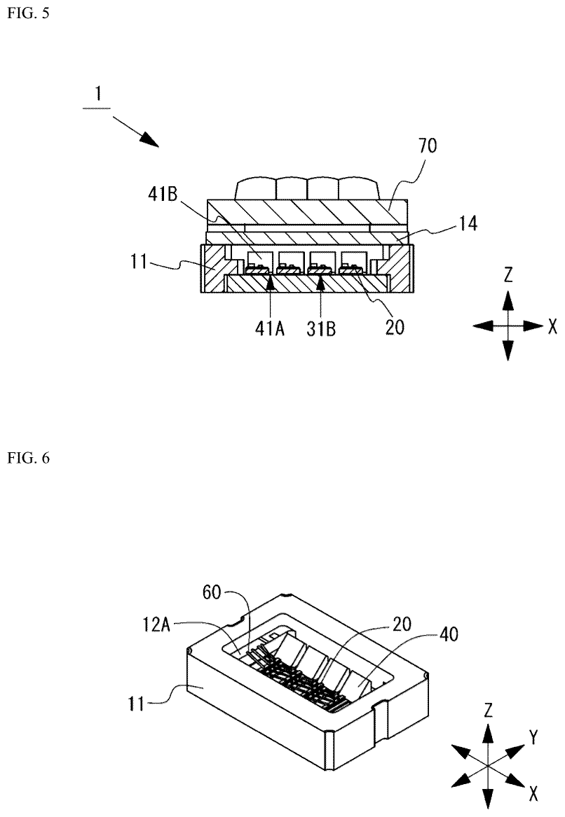

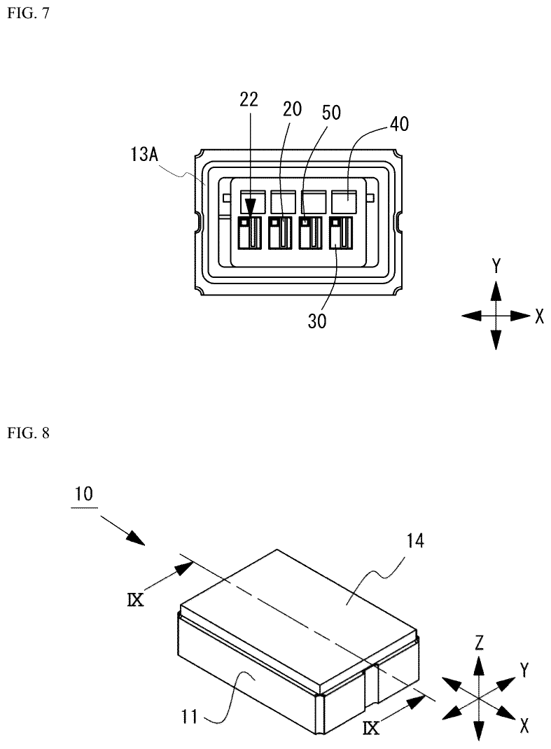

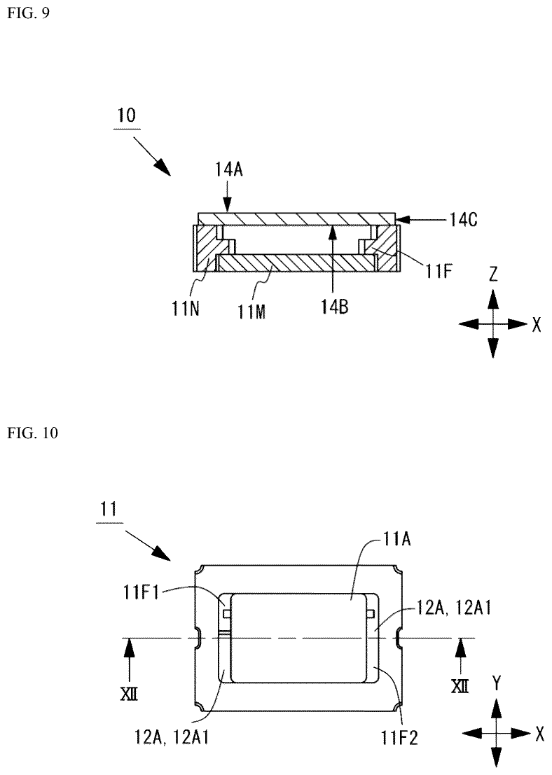

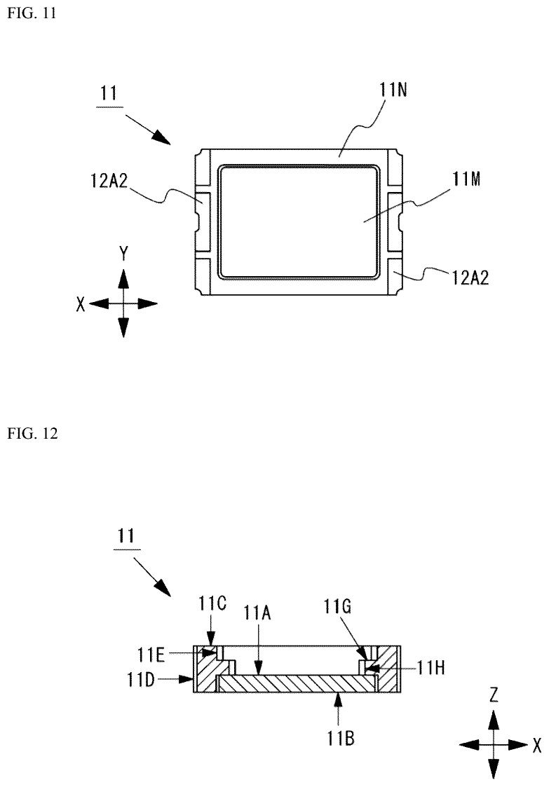

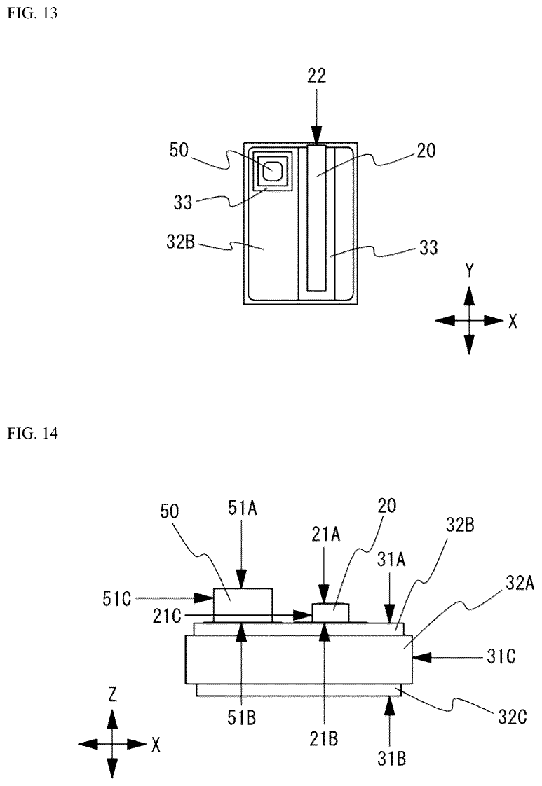

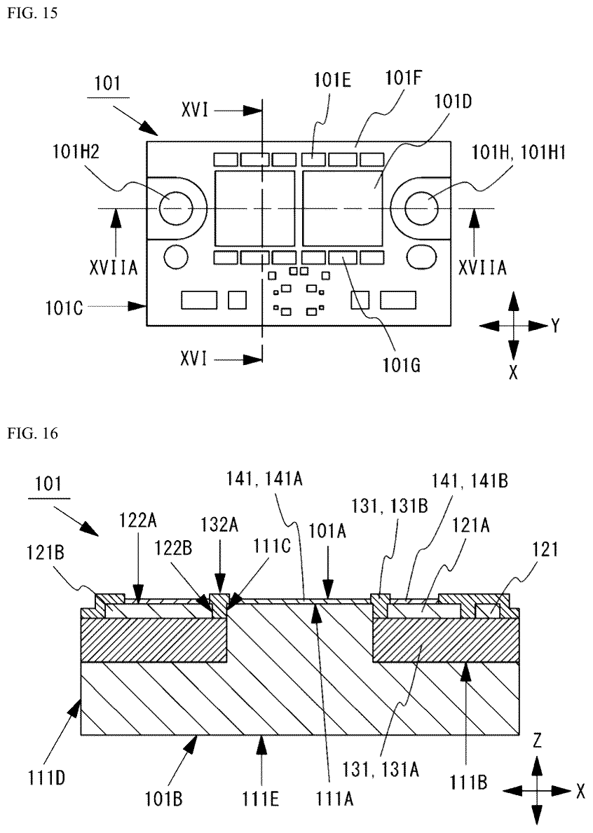

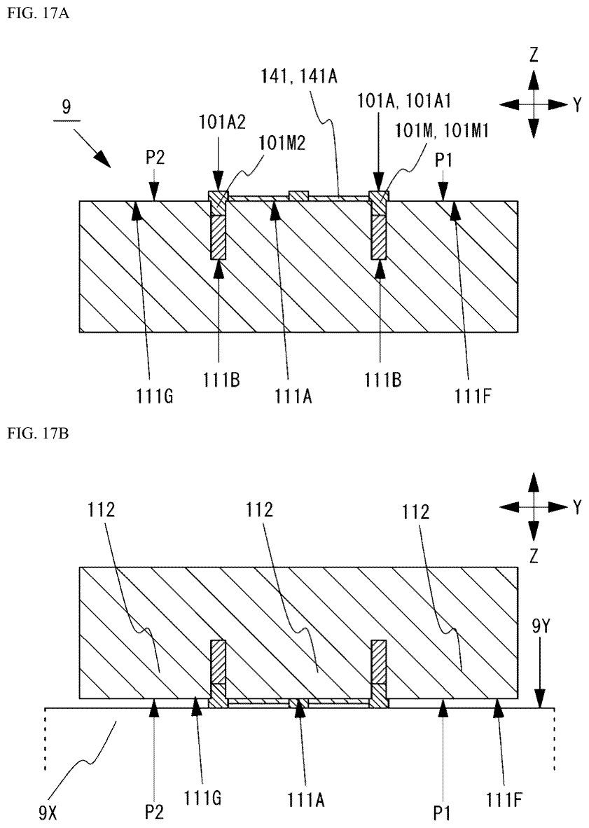

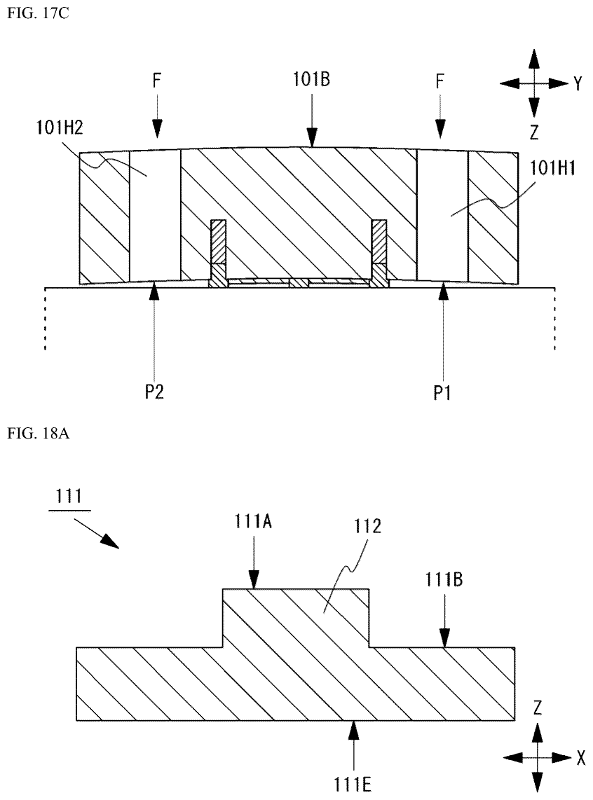

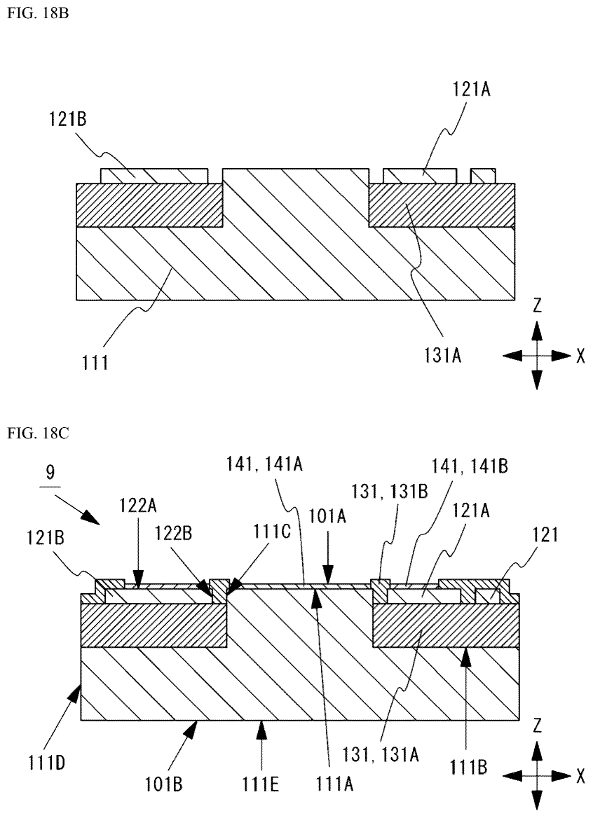

A light-emitting device 1 according to a first embodiment will now be described. FIGS. 1 to 18C are schematic drawings for describing an exemplary configuration of a light-emitting module 901. FIG. 1 is a top view of the light-emitting module 901. FIG. 2 is a perspective view of the light-emitting module 901 in a state of not being fixed to a heat sink 401. FIG. 3 is a perspective view of a light-emitting device 1. FIG. 4 is a side view of the light-emitting device 1. FIG. 5 is a cross-sectional view of the light-emitting device 1 taken along a cross-sectional line V-V in FIG. 3. FIG. 6 is a perspective view illustrating components disposed inside the light-emitting device 1. FIG. 7 is a top view illustrating components disposed inside the light-emitting device 1. A wiring line 60 illustrated in FIG. 6 is omitted in FIG. 7. FIG. 8 is a perspective view of a package 10. FIG. 9 is a cross-sectional view of the package 10 taken along a cross-sectional line IX-IX in FIG. 8. FIG. 10 is a top view of a base 11. FIG. 11 is a bottom view of the base 11. FIG. 12 is a cross-sectional view of the base 11 taken along a cross-sectional line XII-XII in FIG. 10. FIG. 13 is a top view of a state in which a light-emitting element 20 and a protective element 50 are disposed on a submount 30. FIG. 14 is a side view of the state in which the light-emitting element 20 and the protective element 50 are disposed on the submount 30. FIG. 15 is a top view of a wiring substrate 101. FIG. 16 is a cross-sectional view of the wiring substrate 101 taken along a cross-sectional line XVI-XVI in FIG. 15. FIGS. 17A to 17C are cross-sectional views for describing each step in the manufacturing method of the wiring substrate 101. All cross-sectional views of FIGS. 17A to 17C are cross-sectional views at positions corresponding to a cross-sectional line XVIIA-XVIIA in FIG. 15. FIGS. 18A to 18C are cross-sectional views for describing each step in the manufacturing method of a substrate 9. All cross-sectional views of FIGS. 18A to 18C are cross-sectional views at positions corresponding to a cross-sectional line XVI-XVI in FIG. 15.

The light-emitting module 901 includes a plurality of components. The plurality of components included in the light-emitting module 901 include one or more light-emitting devices 1, the wiring substrate 101, a connector 201, a thermistor 301, the heat sink 401, and one or more fixing members 501.

The light-emitting module 901 may also include a component other than these components. For example, the light-emitting module 901 may include a light-emitting device different from the light-emitting device 1. The light-emitting module 901 need not include some of the plurality of components described above.

The light-emitting device 1 includes a plurality of components. The plurality of components include the package 10, one or more of the light-emitting elements 20, one or more of the submounts 30, one or more reflective members 40, one or more of the protective elements 50, a plurality of the wiring lines 60, and an optical member 70.

The light-emitting device 1 may include a component other than the components described above. For example, the light-emitting device 1 may further include a light-emitting element different from the one or more light-emitting elements 20. The light-emitting device 1 need not include some of the components described above.

Firstly, each of the components will be described.

### Package 10

The package 10 includes the base 11 and a lid body 14. The lid body 14 is bonded to the base 11 to form the package 10. An internal space in which other components are disposed is defined in the package 10. The internal space is a closed space surrounded by the base 11 and the lid body 14. The internal space can also be a sealed space in a vacuum or airtight state.

The outer edge shape of the package 10 in a top view is rectangular. This rectangular shape can be a rectangular shape with long sides and short sides. In the illustrated package 10, the long-side direction of the rectangular shape is the same direction as the X direction, and the short-side direction of the rectangular shape is the same direction as the Y direction. The outer edge shape of the package 10 in a top view need not be rectangular.

The internal space in which other components are disposed is formed in the package 10. A first upper surface 11A of the package 10 is a part of a region defining the internal space. In addition, inner lateral surfaces 11E and the lower surface 14B of the package 10 are a part of the region defining the internal space.

The base 11 has the first upper surface 11A and a lower surface 11B. The base 11 has a second upper surface 11C. The base 11 has one or more outer lateral surfaces 11D. The base 11 has one or more inner lateral surfaces 11E. The one or more outer lateral surfaces 11D meet the second upper surface 11C. The one or more outer lateral surfaces 11D meet the lower surface 11B. The one or more inner lateral surfaces 11E meet the second upper surface 11C.

The outer edge shape of the base 11 in a top view is rectangular. The outer edge shape of the base 11 in a top view is the outer edge shape of the package 10. The outer edge shape of the first upper surface 11A in a top view is rectangular. This rectangular shape can be a rectangular shape with long sides and short sides. The long-side direction of the first upper surface 11A is parallel to the long-side direction of the outer edge shape of the base 11. The outer edge shape of the first upper surface 11A in a top view need not be rectangular.

In a top view, the first upper surface 11A is surrounded by the second upper surface 11C. The second upper surface 11C is an annular surface surrounding the first upper surface 11A in a top view. The second upper surface 11C is a rectangular annular surface. Here, a frame defined by an inner edge of the second upper surface 11C is referred to as an inner frame of the second upper surface 11C, and a frame defined by an outer edge of the second upper surface 11C is referred to as an outer frame of the second upper surface 11C.

The base 11 has a recessed portion surrounded by the frame formed by the second upper surface 11C. The recessed portion defines a portion recessed downward from the second upper surface 11C in the base 11. The first upper surface 11A is a part of the recessed portion. The one or more inner lateral surfaces 11E are a part of the recessed portion. The second upper surface 11C is located above the first upper surface 11A.

The base 11 includes one or more step portions 11F. Each of the step portions 11F includes an upper surface 11G and a lateral surface 11H that meets the upper surface 11G and extends downward from the upper surface 11G. Here, one step portion 11F has only one upper surface 11G and only one lateral surface 11H. The upper surface 11G meets the inner lateral surface 11E. The lateral surface 11H meets the first upper surface 11A.

One or each of the step portions 11F is formed on an inner side of the inner frame of the second upper surface 11C in a top view. One or each of the step portions 11F is formed along a part of or the entire inner lateral surface 11E in a top view. In the base 11, the lateral surface 11H is an inner lateral surface, but the lateral surface 11H and the inner lateral surface 11E are different surfaces. One or each of the inner lateral surfaces 11E and one or each of the lateral surfaces 11H are perpendicular to the first upper surface 11A. The description “perpendicular” as used herein allows for a difference within ±3 degrees.

The one or more step portions 11F can include a first step portion 11F1 and a second step portion 11F2. The first step portion 11F1 and the second step portion 11F2 are provided at positions where the respective lateral surfaces 11H are opposed to each other. The first step portion 11F1 and the second step portion 11F2 are provided on sides of the short sides of the inner frame of the second upper surface 11C.

The base 11 includes a base portion 11M and a frame portion 11N. The base portion 11M and the frame portion 11N may be members made of mutually different materials. The base 11 can be configured to include a base member corresponding to the base portion 11M and a frame member corresponding to the frame portion 11N.

The base portion 11M includes the first upper surface 11A. The frame portion 11N includes the second upper surface 11C. The frame portion 11N includes the one or more outer lateral surfaces 11D and the one or more inner lateral surfaces 11E. The frame portion 11N includes the one or more step portions 11F.

The lower surface of the base portion 11M constitutes a part or the entire region of the lower surface 11B of the base 11. When the lower surface of the base portion 11M constitutes a part of the region of the lower surface 11B of the base 11, the lower surface of the frame portion 11N constitutes the remaining region of the lower surface 11B of the base 11.

The base 11 includes a plurality of wiring portions 12A. The wiring portions 12A include one or more first wiring portions 12A1 disposed in the internal space of the package 10 and one or more second wiring portions 12A2 provided on the outer surface of the package 10.

One or each of the first wiring portions 12A1 is provided on the upper surface 11G of the step portion 11F. The base 11 includes the one or more first wiring portions 12A1 provided on the upper surface 11G of the first step portion 11F1. The base 11 includes the one or more first wiring portions 12A1 provided on the upper surface 11G of the second step portion 11F2.

One or each of the second wiring portions 12A2 is provided on the lower surface 11B of the package 10. One or each of the second wiring portions 12A2 is provided on the lower surface of the frame portion 11N. The second wiring portion 12A2 may be provided on an outer surface different from the lower surface 11B of the package 10.

When the base 11 is divided into two regions by a virtual line passing through the lateral surface 11H of the first step portion 11F1 and parallel to the lateral surface 11H in a top view, the base 11 has the one or more second wiring portions 12A2 provided on the lower surface 11B of the base 11 in a region including the upper surface 11G of the first step portion 11F1.

When the base 11 is divided into two regions by a virtual line passing through the lateral surface 11H of the second step portion 11F2 and parallel to the lateral surface 11H in a top view, the base 11 has the one or more second wiring portions 12A2 provided on the lower surface 11B of the base 11 in a region including the upper surface 11G of the second step portion 11F2.

In the base 11, one or each of the first wiring portions 12Al is electrically connected to the second wiring portion 12A2. The one or more first wiring portions 12A1 are electrically connected to the mutually different second wiring portions 12A2.

The base 11 includes a bonding pattern 13A. The bonding pattern 13A is provided on the second upper surface 11C. The bonding pattern 13A is provided annularly. The bonding pattern 13A is provided in a rectangular annular shape. In a top view, the first upper surface 11A is surrounded by the bonding pattern 13A.

The base 11 can be formed using a ceramic as a main material, for example. Examples of the ceramic as the main material of the base 11 include aluminum nitride, silicon nitride, aluminum oxide, and silicon carbide.

The main material as used herein refers to a material that accounts for the greatest proportion of a target formed product in terms of mass or volume. When a target formed product is formed of a single material, the material is the main material. In other words, when a certain material is the main material, the proportion of the material may be 100%.

The base 11 may be formed using a base member and a frame member formed of main materials different from each other. The base member can be formed using a main material having excellent heat dissipation, for example, a metal or a composite containing a metal, graphite, or diamond. Examples of the metal as the main material of the base member include, for example, copper, aluminum, and iron. Examples of the composite containing the metal as the main material of the base member include, for example, copper-molybdenum or copper-tungsten. The frame member can be formed using, as a main material, for example, any of the ceramics exemplified above as the main material of the base 11.

The wiring portion 12A can be formed using a metal material as a main material, for example. Examples of the metal material as the main material of the wiring portion 12A include single-component metals, such as Cu, Ag, Ni, Au, Ti, Pt, Pd, Cr, and W, and alloys containing any of these metals. The wiring portion 12A can be constituted by one or more metal layers, for example.

The bonding pattern 13A can be formed using a metal material as a main material, for example. Examples of the metal material as the main material of the bonding pattern 13A include single-component metals, such as Cu, Ag, Ni, Au, Sn, Ti, and Pd, and alloys containing any of these metals. The bonding pattern 13A can be constituted by one or more metal layers, for example.

The lid body 14 has an upper surface 14A and a lower surface 14B. The lid body 14 also has one or more lateral surfaces 14C. The lid body 14 is formed of a flat plate with a rectangular parallelepiped shape. The shape of the lid body 14 need not be a rectangular parallelepiped.

The lid body 14 is bonded to the base 11. The lower surface 14B of the lid body 14 is bonded to the second upper surface 11C of the base 11. The lid body 14 is bonded to the bonding pattern 13A of the base 11. The lid body 14 is bonded to the base 11 via an adhesive.

The lid body 14 has light transmissivity to transmit light. The light transmissivity as used herein refers to that the transmittance of light incident on the lid body 14 is equal to or more than 80%. The lid body 14 may partially include a non-light transmitting region (a region with no light transmissivity).

The lid body 14 can be formed using glass as a main material, for example. The lid body 14 can also be formed using sapphire as a main material, for example.

### Light-Emitting Element 20

The light-emitting element 20 has an upper surface 21A, a lower surface 21B, and a plurality of lateral surfaces 21C. The shape of the upper surface 21A is rectangular. The rectangular shape is a rectangular shape having long sides and short sides. The outer shape of the light-emitting element 20 in a top view is rectangular. The rectangular shape is a rectangular shape having long sides and short sides. The shape of the upper surface 21A and the outer shape of the light-emitting element 20 in a top view are not limited thereto.

The light-emitting element 20 has a light-emitting surface 22 from which light is emitted. For example, the lateral surface 21C can serve as the light-emitting surface 22. The lateral surface 21C serving as the light-emitting surface 22 meets a short side of the upper surface 21A. Also, for example, the upper surface 21A can serve as the light-emitting surface 22. The light-emitting element 20 has one or more light-emitting surfaces 22.

As the light-emitting element 20, for example, a light-emitting element that emits blue light can be employed. Also, for example, as the light-emitting element 20, a light-emitting element that emits green light can be employed. Also, for example, as the light-emitting element 20, a light-emitting element that emits red light can be employed. As the light-emitting element 20, a light-emitting element that emits light of another color or another wavelength may be employed.

Here, blue light refers to light having a light emission peak wavelength within a range from 420 nm to 494 nm. Green light refers to light having a light emission peak wavelength within a range from 495 nm to 570 nm. Red light refers to light having a light emission peak wavelength within a range from 605 nm to 750 nm.

Examples of the light-emitting element 20 that emits blue light or the light-emitting element 20 that emits green light include a light-emitting element containing a nitride semiconductor. A GaN-based semiconductor, such as GaN, InGaN, or AlGaN, can be employed as the nitride semiconductor. Examples of the light-emitting element 20 that emits red light include a light-emitting element containing an InAlGaP-based semiconductor, a GaInP-based semiconductor, or a GaAs-based semiconductor, such as GaAs or AlGaAs.

As the light-emitting element 20, for example, a semiconductor laser element can be employed. As the light-emitting element 20, a single-emitter semiconductor laser element constituted by one emitter can be employed. Also, as the light-emitting element 20, a multi-emitter semiconductor laser element constituted by a plurality of emitters can be employed. The light-emitting element 20 is not limited to a semiconductor laser element, and may be, for example, a light-emitting diode.

Here, a semiconductor laser element as an example of the light-emitting element 20 will be described.

The semiconductor laser element emits a directional laser beam. Spreading divergent light is emitted from the light-emitting surface 22 of the semiconductor laser element. The light emitted from the semiconductor laser element forms a far-field pattern (hereinafter, referred to as an “FFP”) with an elliptical shape in a plane parallel to the light-emitting surface 22. The FFP indicates a shape or a light intensity distribution of the emitted light at a position spaced apart from the light-emitting surface of the semiconductor laser element.

Here, light passing through the center of the elliptical shape of the FFP, in other words, light having a peak intensity in the light intensity distribution of the FFP is referred to as light traveling along an optical axis or light passing through an optical axis. In the light intensity distribution of the FFP, light having an intensity that is equal to or more than 1/e² with respect to the peak intensity is referred to as a main portion of the light.

The FFP of the light emitted from the semiconductor laser element has an elliptical shape in which the length in a layering direction is greater than that in a direction perpendicular to the layering direction in the plane parallel to the light-emitting surface 22. The layering direction is a direction in which a plurality of semiconductor layers including an active layer are layered in the semiconductor laser element. The direction perpendicular to the layering direction can also be referred to as a plane direction of the semiconductor layer. A long diameter direction of the elliptical shape of the FFP can also be referred to as a fast axis direction of the semiconductor laser element, and a short diameter direction of the elliptical shape of the FFP can also be referred to as a slow axis direction of the semiconductor laser element.

Based on the light intensity distribution of the FFP, an angle at which light having a light intensity of 1/e² of the peak light intensity spreads is referred to as a divergence angle of light of the semiconductor laser element. Here, the divergence angle of light is indicated as an angle formed by light having the peak light intensity (light passing through an optical axis) and light having a light intensity of 1/e² of the peak light intensity. In some cases, the divergence angle of light can also be determined based on, for example, the light intensity that is half of the peak light intensity, other than being determined based on the light intensity of 1/e² of the peak light intensity. In the description herein, the term “divergence angle of light” by itself refers to a divergence angle of light at the light intensity of 1/e² of the peak light intensity.

The divergence angle in the fast axis direction of the light emitted from the semiconductor laser element can be in a range from 20 degrees to less than 80 degrees. The divergence angle of the light in the slow axis direction can be in a range from more than 0 degrees to 20 degrees. The divergence angle of the light in the fast axis direction is greater than the divergence angle of the light in the slow axis direction.

For example, the divergence angle in the fast axis direction of the blue light emitted from the semiconductor laser element can be in a range from 30 degrees to less than 60 degrees, and the divergence angle in the slow axis direction can be in a range from 5 degrees to less than 20 degrees. For example, the divergence angle in the fast axis direction of the green light emitted from the semiconductor laser element can be in a range from 30 degrees to less than 60 degrees, and the divergence angle in the slow axis direction can be in a range from 5 degrees to less than 20 degrees. For example, the divergence angle in the fast axis direction of the red light emitted from the semiconductor laser element can be in a range from 40 degrees to less than 80 degrees, and the divergence angle in the slow axis direction can be in a range from 5 degrees to less than 20 degrees.

### Submount 30

The submount 30 includes an upper surface 31A, a lower surface 31B, and one or more lateral surfaces 31C. It can be said that the upper surface 31A is a mounting surface on which other components are mounted. The shape of the upper surface 31A is rectangular. The rectangular shape of the upper surface 31A can have short sides and long sides. The shape of the upper surface 31A need not be rectangular.

The outer shape of the submount 30 in a top view is rectangular. The rectangular shape of the submount 30 can have short sides and long sides. The outer shape of the submount 30 in a top view need not be rectangular. The submount 30 can have an outer shape having a length in one direction (hereinafter, the direction is referred to as a lateral direction of the submount 30) smaller than a length in a direction (hereinafter, the direction is referred to as a longitudinal direction of the submount 30) perpendicular to the one direction in a top view. In the submount 30 illustrated by the drawings, the lateral direction is the same direction as the X direction, and the longitudinal direction is the same direction as the Y direction.

The submount 30 can include a substrate 32A and an upper metal member 32B. The submount 30 can further include a lower metal member 32C. The upper metal member 32B is provided on the upper surface side of the substrate 32A. The lower metal member 32C is provided on the lower surface side of the substrate 32A. The submount 30 further includes a wiring layer 33. The wiring layer 33 is provided on the upper metal member 32B.

The substrate 32A has an insulating property. The substrate 32A is formed of, for example, silicon nitride, aluminum nitride, or silicon carbide. It is preferable to select a ceramic with relatively good heat dissipation (having high thermal conductivity) as the main material of the substrate 32A.

A metal such as copper and aluminum is used as the main material of the upper metal member 32B. The upper metal member 32B includes one or more metal layers. The upper metal member 32B can include a plurality of metal layers formed of different metals as main materials.

A metal such as copper or aluminum is used as the main material of the lower metal member 32C. The lower metal member 32C includes one or more metal layers. The lower metal member 32C can include a plurality of metal layers formed of different metals as main materials.

The wiring layer 33 can be formed using a metal. For example, the wiring layer 33 can be formed using AuSn solder (a metal layer of AuSn).

For example, the length of the submount 30 in the short-side direction or the lateral direction is in a range from 300 μm to 2000 μm. The length of the submount 30 in the long-side direction or the longitudinal direction is in a range from 500 μm to 10000 μm. The difference between the length of the submount 30 in the longitudinal direction and the length in the lateral direction is in a range from 200 μm to 9000 μm.

For example, the thickness of the submount 30 (the width in a direction perpendicular to the upper surface 31A) is in a range from 100 μm to 500 μm. For example, the thickness of the substrate 32A is in a range from 100 μm to 400 μm. For example, the thickness of the upper metal member 32B is in a range from 20 μm to 200 μm. For example, the thickness of the lower metal member 32C is in a range from 20 μm to 200 μm. For example, the thickness of the wiring layer 33 is in a range from 0.1 μm to 5 μm.

### Reflective Member 40

The reflective member 40 has a lower surface 41A, and a light-reflective surface 41B that reflects light. The light-reflective surface 41B is inclined with respect to the lower surface 41A. A straight line connecting a lower end and an upper end of the light-reflective surface 41B is inclined with respect to the lower surface 41A. An angle at which the light-reflective surface 41B is inclined with respect to the lower surface 41A is referred to as an inclination angle of the light-reflective surface 41B.

The light-reflective surface 41B is a flat surface. The light-reflective surface 41B may be a curved surface. The inclination angle of the light-reflective surface 41B is 45 degrees. The light-reflective surface 41B need not have an inclination angle of 45 degrees.

As the main material of the reflective member 40, glass or metal can be used. A heat-resistant material is preferably used as the main material of the reflective member 40. As the main material, for example, a glass such as quartz glass or borosilicate glass (BK7), or a metal such as Al can be used. The reflective member 40 can also be formed using Si as the main material.

When the main material is a reflective material such as Al, the light-reflective surface 41B can be formed of the main material. Instead of forming the light-reflective surface 41B with the main material, a general form of the reflective member 40 may be formed with the main material, and the light-reflective surface 41B may be formed on a surface of the general form. In this case, the light-reflective surface 41B can be formed using, for example, a layer of a metal such as Ag or Al, or a dielectric multilayer film of Ta₂O₅/SiO₂, TiO₂/SiO₂, or Nb₂O₅/SiO₂.

In the light-reflective surface 41B, the reflectance with respect to the peak wavelength of the light irradiated on the light-reflective surface 41B is equal to or more than 90%. The reflectance may be equal to or more than 95%. The reflectance may be equal to or more than 99%. The light reflectance is equal to or less than 100% or is less than 100%.

### Protective Element 50

The protective element 50 has an upper surface 51A, a lower surface 51B, and one or more lateral surfaces 51C. The shape of the protective element 50 is a rectangular parallelepiped. The shape of the protective element 50 need not be a rectangular parallelepiped.

The protective element 50 reduces breakage of a specific element (the semiconductor laser element, for example) due to an excessive current flowing through the element. The protective element 50 is, for example, a Zener diode. A Zener diode formed of Si can be used.

### Wiring Line 60

The wiring line 60 is a linear conductive material having bonding portions at both ends. The bonding portions at both ends serve as portions for bonding with other components. The wiring line 60 is used for electrical connection between two components. The wiring line 60 is, for example, a metal wire. The metal used can be, for example, gold, aluminum, silver, or copper.

### Optical Member 70

The optical member 70 has an upper surface 71A, a lower surface 71B, and one or more lateral surfaces 71C. The optical member 70 imparts an optical action to light that is incident on the optical member 70. Examples of the optical action imparted to the light by the optical member 70 include condensing, collimation, diffusion, polarization, diffraction, multiplexing, light guiding, reflection, and wavelength conversion.

The optical member 70 has an optical action surface that imparts the optical action. The upper surface 71A, the lower surface 71B, or the lateral surface 71C can serve as the optical action surface. Alternatively, the optical action surface may be provided at a position different from the upper surface 71A, the lower surface 71B, or the lateral surface 71C. For example, the optical action surface may be formed not on a surface of the optical member 70 but on an inner side of the optical member 70.

The optical member 70 can have one or more lens surfaces 71D. The lens surface 71D is the optical active surface of the optical member 70. The optical member 70 having the lens surface 71D may be referred to as a lens member. Light passing through the lens surface 71D and emitted from the optical member 70 is imparted an optical action of condensing, diffusion, or collimation by the optical member 70. For example, the optical member 70 is a collimating lens that collimates light that is incident on the optical member 70 and emits the collimated light.

One or each of the lens surfaces 71D is provided on the upper surface 71A side. The lens surface 71D may be provided on the lower surface 71B side. The upper surface 71A and the lower surface 71B are flat surfaces. The one or each of the lens surfaces 71D meets the upper surface 71A. In a top view, the one or each of the lens surfaces 71D is surrounded by the upper surface 71A.

The outer shape of the optical member 70 in a top view is rectangular. The outer shape of the optical member 70 in a top view need not be rectangular. The lower surface 71B is a flat surface. The lens surface 71D is not formed on the lower surface 71B side of the optical member 70. The shape of the lower surface 71B is rectangular. The shape of the lower surface 71B need not be rectangular.

In the optical member 70, a portion overlapping with the lens surface 71D in a top view is a lens portion 72A. In the optical member 70, a portion overlapping with the upper surface 71A in a top view is a non-lens portion 72B. The lower surface 71B has a region constituting the lower surface of one or each of the lens portions 72A and a region constituting the lower surface of the non-lens portion 72B.

The optical member 70 can have a plurality of the lens surfaces 71D formed continuously in one direction. A direction in which the plurality of lens surfaces 71D are aligned in a top view is referred to as a coupling direction of the lens. In the illustrated optical member 70, the coupling direction is the same direction as the X direction.

The plurality of lens surfaces 71D are formed such that the vertices of the respective lens surfaces 71D are provided on one straight line. The imaginary straight line connecting the respective vertices is parallel to the lower surface 71B of the optical member 70. The term “parallel” used here allows a difference within ±5 degrees.

The curvatures of two or more lens surfaces 71D, that is, some or all of the plurality of lens surfaces 71D can be the same. The plurality of lens surfaces 71D can all have the same curvatures.

The optical member 70 has light transmissivity. In the optical member 70, the light transmittance with respect to the peak wavelength of light incident on the optical member 70 is equal to or more than 80%. The optical member 70 may include a region having light transmissivity and a region having no light transmissivity (hereinafter, referred to as a non-light transmitting region). In the non-light-transmitting region, the light transmittance with respect to the peak wavelength of light incident on the optical member 70 is equal to or less than 50%. The optical member 70 can be formed using, for example, glass such as BK7.

### Wiring Substrate 101

The wiring substrate 101 has an upper surface 101A, a lower surface 101B, and one or more lateral surfaces 101C. The wiring substrate 101 has a plate-like shape. The outer edge shape of the wiring substrate 101 in a top view is rectangular. This rectangular shape can be a rectangular shape with long sides and short sides. In the package 10 illustrated by the drawings, a short-side direction of the rectangular shape is the same direction as the X direction, and a long-side direction is the same direction as the Y direction.

The wiring substrate 101 includes heat dissipation portions 101D, electrode portions 101E, and an insulating portion 101F. The heat dissipation portion 101D functions as a heat dissipation path for heat generated from other components mounted on the wiring substrate 101. It can be said that the heat dissipation portion 101D is a mounting portion having one or more mounting surfaces on which other components are mounted. The electrode portion 101E is electrically connected to the other components mounted on the wiring substrate 101.

The insulating portion 101F insulates the heat dissipation portion 101D and the electrode portion 101E. The insulating portion 101F is provided to insulate electrical connection between the heat dissipation portion 101D and the electrode portion 101E in the wiring substrate 101.

The upper surface 101A of the wiring substrate 101 includes a region serving as one or more mounting surfaces of the heat dissipation portion 101D, a region serving as upper surfaces of the electrode portions 101E, and a region serving as the upper surface of the insulating portion 101F. The upper surface of the insulating portion 101F is located above the upper surface of the heat dissipation portion 101D. The upper surface of the insulating portion 101F is located above the upper surface of the electrode portion 101E.

The “thickness” of the wiring substrate 101 here refers to a width in a vertical direction from the lower surface 101B to the upper surface 101A. In the illustrated wiring substrate 101, the vertical direction is the same direction as the Z direction.

In the upper surface 101A, the thickness of the wiring substrate 101 in the region serving as the one or more mounting surfaces of the heat dissipation portion 101D is smaller than the thickness of the wiring substrate 101 in the region serving as the upper surface of the insulating portion 101F. In the upper surface 101A, the thickness of the wiring substrate 101 in the region serving as the upper surfaces of the electrode portions 101E is smaller than the thickness of the wiring substrate 101 in the region serving as the upper surface of the insulating portion 101F.

When the upper surface 101A is divided into three regions by two virtual straight lines parallel to the short-side direction that trisects a width in the long-side direction of the wiring substrate 101 in a top view, at least a part of the one or more mounting surfaces of the heat dissipation portion 101D is disposed in the middle region. The one or more mounting surfaces have the largest area disposed in the middle region among the three regions.

The insulating portion 101F includes a protruding portion 101M (the third protruding portion) protruding upward from the mounting surface of the heat dissipation portion 101D. The protruding portion 101M has an upper surface located above the mounting surface. In the wiring substrate 101, the one or more protruding portions 101M may be provided such that the upper surface located above the one or more mounting surfaces is provided in two regions between which the one or more mounting surfaces are interposed in a top view.

The wiring substrate 101 includes a first protruding portion 101M1 having a first upper surface located above the mounting surface and a second protruding portion 101M2 having a second upper surface located above the mounting surface, and the one or more mounting surfaces are located between the first upper surface and the second upper surface in a top view.

The protruding portion 101M surrounds the mounting surface of the heat dissipation portion 101D in a top view. In a top view, the mounting surface is surrounded by the upper surface of the protruding portion 101M located above the mounting surface and is located inside the upper surface. The protruding portion 101M surrounding the mounting surface of the heat dissipation portion 101D in a top view can be configured by one continuously connected protruding portion. A first upper surface 101A1 and a second upper surface 101A2 can be provided on the same plane by being configured by the continuously connected protruding portions.

The wiring substrate 101 may have a plurality of the protruding portions 101M spaced apart from one another. That is, the respective first protruding portion 101M1 and second protruding portion 101M2 may be spaced apart or may be a part of one continuously connected protruding portions 101M. In the illustrated wiring substrate 101, the first protruding portion 101M1 and the second protruding portion 101M2 are a part of one protruding portion 101M that surrounds the mounting surface in a top view.

In the illustrated wiring substrate 101, for example, two portions between which the one or more mounting surfaces are interposed in the Y direction in a top view can be the respective first protruding portion 101M1 and second protruding portion 101M2. For example, two portions between which the mounting surface is interposed in the X direction in a top view can be the respective first protruding portion 101M1 and second protruding portion 101M2.

The upper surface of the protruding portion 101M is located above the mounting surface of the heat dissipation portion 101D in a range from 20 μm to 100 μm. The upper surface of the protruding portion 101M is preferably located above the mounting surface of the heat dissipation portion 101D in a range from 20 μm to 50 μm. By configuring the upper surface of the protruding portion 101M above the mounting surface, it is possible to assist formation of warp in the wiring substrate 101 described later. Setting a difference between the upper surface of the protruding portion 101M and the mounting surface in the vertical direction to 50 μm or less can suppress influence of the upper surface of the protruding portion 101M when other components are mounted on the mounting surface.

The wiring substrate 101 includes the heat dissipation member 111, a plurality of the electrode members 121, and one or more insulating members 131. The heat dissipation portion 101D includes the heat dissipation member 111, the electrode portion 101E includes the plurality of electrode members 121, and the insulating portion 101F includes the one or more insulating members 131.

The wiring substrate 101 includes one or more of the metal layers 141. The one or more metal layers 141 include one or more first metal layers 141A included in the heat dissipation portion 101D and one or more second metal layers 141B included in the electrode portion 101E.

The wiring substrate 101 is provided with one or more through holes 101H. The one or more through holes 101H include a through hole 101H used for fixing the wiring substrate 101 to another member (component). For example, a screw is fitted into the through hole 101H to fix the wiring substrate 101 to another member. The one or more through holes 101H include the through hole 101H used for determining positions when fixing the wiring substrate 101 to another member.

The one or more through holes 101H are holes provided in the vertical direction from the upper surface 101A to the lower surface 101B of the wiring substrate 101. In the wiring substrate 101, the one or more through holes 101H are provided in an outer peripheral portion located outside the one or more mounting surfaces of the heat dissipation portion 101D in a top view.

The one or more through holes 101H include a first through hole 101H1 and a second through hole. The first through hole 101H1 is provided at a first position P1 of the upper surface 101A in a top view. The second through hole 101H2 is provided at a second position P2 of the upper surface 101A in a top view.

In a top view, the one or more mounting surfaces of the heat dissipation portion 101D are located between the first through hole 101H1 and the second through hole 101H2. In a top view, the one or more mounting surfaces are interposed between the first position P1 and the second position P2. In a top view, a virtual straight line passing through the first through hole 101H1 and the second through hole 101H2 passes through the one or more mounting surfaces. In a top view, a virtual line segment connecting the first position P1 and the second position P2 passes through the one or more mounting surfaces.

In a top view, the first position P1 and the second position P2 are positions that avoid between the protruding portion 101M and the mounting surface. That is, the first through hole 101H1 and the second through hole 101H2 are not provided between the upper surface of the protruding portion 101M and the mounting surface in a top view.

In a top view, the first position P1 and the second position P2 are positions that avoid between the first upper surface 101A1 and the mounting surface and are positions avoiding between the second upper surface 101A2 and the mounting surface. The first through hole 101H1 and the second through hole 101H2 are not provided between the first upper surface 101A1 and the mounting surface of the heat dissipation portion 101D nor between the second upper surface 101A2 and the mounting surface in a top view.

When the upper surface 101A is divided into the three regions by the two virtual straight lines parallel to the short-side direction that trisects the width in the long-side direction of the wiring substrate 101 in a top view, the first through hole 101H1 is provided in one of regions at both ends, and the second through hole 101H2 is provided in the other region.

In a top view, with respect to the first through hole 101H1 and the second through hole 101H2 provided at the positions between which the one or more mounting surfaces of the heat dissipation portion 101D are interposed in a first direction, the first protruding portion 101M1 and the second protruding portion 101M2 may be provided at positions between which the one or more mounting surfaces are interposed in the first direction. In the case, in the illustrated wiring substrate 101, the first direction and the Y direction are the same direction.

In a top view, the first upper surface 101A1 is provided at a position away from the mounting surface in the first direction, and the first through hole 101H1 is provided at a position away from the first upper surface 101A1 in the first direction. In a top view, the second upper surface 101A2 is provided at a position away from the mounting surface in a direction opposite to the first direction, and the second through hole 101H2 is provided at a position away from the second upper surface 101A2 in the direction opposite to the first direction. With such an arrangement and a manufacturing method described later, the direction of warp in the wiring substrate 101 can be controlled.

In a top view, with respect to the first through hole 101H1 and the second through hole 101H2 provided at the positions between which the one or more mounting surfaces of the heat dissipation portion 101D are interposed in the first direction, the first protruding portion 101M1 and the second protruding portion 101M2 may be provided at positions between which the mounting surface is interposed in a second direction intersecting with the first direction. For example, the second direction is a direction perpendicular to the first direction in a top view. In the case, in the illustrated wiring substrate 101, the first direction is the same direction as the Y direction, and the second direction is the same direction as the X direction.

In a top view, the electrode portions 101E are provided in two regions between which the mounting surface of the heat dissipation portion 101D is interposed. Between the two regions, the mounting surface is interposed in the direction perpendicular to the first direction. In a top view, a virtual straight line passing through the two regions passes through the mounting surface. The straight line does not pass through the first through hole 101H1 nor the second through hole 101H2.

The lower surface 101B of the wiring substrate 101 is warped in a predetermined direction (see FIG. 17C). By manufacturing the wiring substrate 101 such that the lower surface 101B is warped in a desired direction, even when the large number of wiring substrates 101 are manufactured, the directions of the warps are the same. Therefore, it is possible to reduce variations in heat dissipation performance among the wiring substrates 101. For example, the lower surface 101B of the wiring substrate 101 has a warp such that the center protrudes with respect to both ends.

The lower surface 101B of the wiring substrate 101 is warped with a shape in which a virtual line segment connecting a point located immediately below the first upper surface 101A1 and a point located immediately below the second upper surface 101A2 on the lower surface 101B passes through the inside of the wiring substrate 101. The point located directly below the mounting surface on the lower surface 101B is located below the line segment. By warping the lower surface 101B of the wiring substrate 101 in this way, when a heat sink is mounted on the lower surface 101B, the portion immediately below the mounting surface easily comes into contact with the heat sink, and therefore the wiring substrate 101 having excellent heat dissipation property can be achieved.

The wiring substrate 101 can be manufactured by a manufacturing method including a step of preparing the substrate 9 (hereinafter referred to as a first step), a step of disposing the substrate 9 on a support member 9X (hereinafter referred to as a second step), and a step of providing the through hole 101H in the substrate 9 (hereinafter referred to as a third step).

As illustrated in FIG. 17A, in the first step, the substrate 9 in which the first upper surface 101A1 and the second upper surface 101A2 located above the one or more mounting surfaces are provided at positions between which the one or more mounting surfaces are interposed in a top view is prepared. At the stage of the first step, the first through hole 101H1 or the second through hole 101H2 is not provided in the substrate 9. The substrate 9 prepared in the first step can be a substrate in a state where the wiring substrate 101 is completed when the first through hole 101H1 and the second through hole 101H2 are provided.

As illustrated in FIG. 17B, in the second step, the substrate 9 is disposed on the support member 9X having a support surface 9Y. At this time, the substrate 9 is disposed on the support member 9X such that the first upper surface 101A1 and the second upper surface 101A2 of the substrate 9 face the support surface 9Y.

As illustrated in FIG. 17C, in the third step, the first through hole 101H1 is provided at the first position P1 and the second through hole 101H2 is provided at the second position P2 from the lower surface side toward the upper surface side of the substrate 9. The lower surface 101B of the substrate 9 (the wiring substrate 101) has a warp due to the influence of a force F applied from the lower surface side toward the upper surface side of the substrate when the through holes 101H are provided at the first position P1 and the second position P2. A warp occurs in a predetermined direction due to the relationship between the positions and heights of the one or more mounting surfaces, the first upper surface 101A1, and the second upper surface 101A2. In FIG. 17C, the lower surface 101B of the substrate 9 has a convex warp. Therefore, the wiring substrate 101 having an excellent heat dissipation effect can be implemented.

The first through hole 101H1 and the second through hole 101H2 are provided at positions away in the long-side direction in a rectangular outer edge shape of the wiring substrate 101 in a top view. The first through hole 101H1 and the second through hole 101H2 are provided at positions closer to the outer edge of the wiring substrate 101 than the center of the wiring substrate 101 in the long-side direction in a top view. When the long-side direction is selected rather than the short-side direction, the lower surface 101B of the wiring substrate 101 is easily warped.

The substrate prepared in the first step can be manufactured by a manufacturing method including a step of preparing the heat dissipation member 111 (hereinafter referred to as a fourth step), a step of providing the plurality of electrode members 121 (hereinafter referred to as a fifth step), and a step of providing an insulating member (hereinafter referred to as a sixth step).

As illustrated in FIG. 18A, the heat dissipation member 111 prepared in the fourth step has a first upper surface 111A. The heat dissipation member 111 has a second upper surface 111B at a position lower than the first upper surface 111A. The heat dissipation member 111 has one or more first lateral surfaces 111C that meet the first upper surface 111A. The heat dissipation member 111 has one or more second lateral surfaces 111D that respectively meet the one or more second upper surfaces 111B. The heat dissipation member 111 has a lower surface 111E.

The heat dissipation member 111 has a third upper surface 111F at a position higher than the second upper surface 111B. The heat dissipation member 111 has a fourth upper surface 111G at a position higher than the second upper surface 111B. The third upper surface 111F is provided in a region including the first position P1 and the vicinity of the first position P1. The fourth upper surface 111G is provided in a region including the second position P2 and the vicinity of the second position P2.

In the third step, the first through hole 101H1 is provided such that the first through hole 101H1 is located inside the outer edge of the third upper surface 111F in a top view. In the third step, the second through hole 101H2 is provided such that the second through hole 101H2 is located inside the outer edge of the fourth upper surface 111G in a top view.

The third upper surface 111F is at the same height as the first upper surface 111A. The fourth upper surface 111G is at the same height as the first upper surface 111A. These heights of the upper surfaces do not need to be the same. The third upper surface 111F is located below the first upper surface 101A1 of the first protruding portion 101M1. The fourth upper surface 111G is located below the second upper surface 101A2 of the second protruding portion 101M2.

The heat dissipation member 111 includes one or more protruding portions 112 formed on the upper surface side. The heat dissipation member 111 includes the one or more protruding portions 112 each protruding from the second upper surface 111B. The one or more protruding portions 112 include the protruding portion 112 having the first upper surface 111A and the one or more first lateral surfaces 111C. The height of the protruding portion 112 of the heat dissipation member 111 (the height from the second upper surface 111B) is smaller than the height from the lower surface 111E to the second upper surface 111B.

The one or more protruding portions 112 have the third upper surface 111F and the fourth upper surface 111G. The one or more protruding portions 112 include the protruding portion 112 having the third upper surface 111F. The one or more protruding portions 112 include the protruding portion 112 having the fourth upper surface 111G.

The first upper surface 111A, the third upper surface 111F, and the fourth upper surface 111G are included in the respective different protruding portions 112. In other words, in the heat dissipation member 111, the protruding portion 112 having the first upper surface 111A, the protruding portion 112 having the third upper surface 111F, and the protruding portion 112 having the fourth upper surface 111G are formed, and these protruding portions are spaced apart from one another in a top view.

The outer edge shape of the heat dissipation member 111 in a top view is rectangular. The rectangular shape is a rectangular shape having long sides and short sides. In the illustrated heat dissipation member 111, the long-side direction is the same direction as the Y direction, and the short-side direction is the same direction as the X direction.

As illustrated in FIG. 18B, in the fifth step, the plurality of electrode members 121 are provided on the heat dissipation member 111. The plurality of electrode members 121 are provided on the second upper surface 111B of the heat dissipation member 111. The plurality of electrode members 121 are provided on the heat dissipation member 111 via the insulating member 131. The one or more insulating members 131 include a first insulating member 131A provided on the second upper surface 111B.

The plurality of electrode members 121 are provided on the first insulating members 131A. The plurality of electrode members 121 are provided in a plurality of regions spaced apart from each other. The heat dissipation member 111 and each of the electrode members 121 are spaced apart from each other. Each of the electrode members 121 is insulated from the heat dissipation member 111 via the first insulating member 131A.

The plurality of electrode members 121 include a first electrode member 121A and a second electrode member 121B. In a top view, the first upper surface 111A is disposed between the first electrode member 121A and the second electrode member 121B. In a top view, the first electrode member 121A, the first upper surface 111A, and the second electrode member 121B are disposed in this order.

The first electrode member 121A and the second electrode member 121B are provided at positions spaced apart from one or each of the protruding portions 112 in a top view. In a top view, the first electrode member 121A and the second electrode member 121B are provided at positions spaced apart from the protruding portion 112 (the fourth protruding portion) having the first upper surface 111A. In a top view, the first electrode member 121A and the second electrode member 121B are provided at positions spaced apart from the protruding portion 112 (the fifth protruding portion) having the third upper surface 111F and the protruding portion 112 (the sixth protruding portion) having the fourth upper surface 111G.

Each of the electrode members 121 has an upper surface 122A and one or more lateral surfaces 122B. In a top view, the first upper surface 111A of the heat dissipation member 111 and the upper surface 122A of each of the electrode members 121 are spaced apart from each other. One or each of the electrode members 121 has the lateral surface 122B opposed to the first lateral surface 111C of the heat dissipation member 111.

In the third step, while the first through hole 101H1 and the second through hole 101H2 are provided at positions between which the protruding portion 112 having the first upper surface 111A is interposed in the first direction in a top view, in the fifth step, the first electrode member 121A and the second electrode member 121B are in a positional relationship of being provided at positions between which the protruding portion 112 having the first upper surface 111A is interposed in the second direction intersecting with the first direction in a top view. The second direction may be a direction perpendicular to the first direction.

The first electrode member 121A and the second electrode member 121B are provided at positions away in the short-side direction of the rectangular outer edge shape of the wiring substrate 101 in a top view. When the short-side direction is selected rather than the long-side direction, the state of warp of the lower surface 101B immediately below the first electrode member 121A and the second electrode member 121B can be matched with the state of warp immediately below the first upper surface 111A, and mounting including the first electrode member 121A and the second electrode member 121B on the mounting surface is easily performed.

As illustrated in FIG. 18C, in the sixth step, the insulating member 131 is provided in a space between the protruding portion 112 having the first upper surface 111A and the electrode member 121. In a top view, the insulating member 131 is provided between the protruding portion 112 and the first electrode member 121A and between this protruding portion 112 and the second electrode member 121B.

In the sixth step, the insulating member 131 is provided in a space between the protruding portion 112 having the first upper surface 111A and the protruding portion 112 having the third upper surface 111F. The insulating member 131 is provided in a space between the protruding portion 112 having the first upper surface 111A and the protruding portion 112 having the fourth upper surface 111G. The insulating members 131 are provided between the protruding portion 112 having the first upper surface 111A and the protruding portion 112 having the third upper surface 111F and between the protruding portion 112 having the first upper surface 111A and the protruding portion 112 having the fourth upper surface 111G in a top view.

The one or more insulating members 131 include a second insulating member 131B provided between the heat dissipation member 111 and each of the electrode members 121. One or each of the first lateral surfaces 111C of the heat dissipation member 111 is covered by the second insulating member 131B. The lateral surface 122B of one or each of the electrode members 121 that is opposed to the first lateral surface 111C is covered by the second insulating member 131B. The second insulating member 131B fills a space between the first lateral surface 111C and the lateral surface 122B.

The second insulating member 131B is provided between the first upper surface 111A and the third upper surface 111F in a top view. The second insulating member 131B is provided between the protruding portion 112 having the first upper surface 111A and the protruding portion 112 having the third upper surface 111F.

The second insulating member 131B is provided between the first upper surface 111A and the fourth upper surface 111G in a top view. The second insulating member 131B is provided between the protruding portion 112 having the first upper surface 111A and the protruding portion 112 having the fourth upper surface 111G.

An upper surface 132A of the second insulating member 131B provided between the first electrode member 121A and the protruding portion 112 having the first upper surface 111A is located above the first upper surface 111A. The upper surface 132A is located above the upper surface 122A of the first electrode member 121A. The second insulating member 131B forms the protruding portion 101M protruding upward from the first upper surface 111A.

The upper surface 132A of the second insulating member 131B provided between the second electrode member 121B and the protruding portion 112 having the first upper surface 111A is located above the first upper surface 111A. The upper surface 132A is located above the upper surface 122A of the second electrode member 121B. The second insulating member 131B forms the protruding portion 101M protruding upward from the first upper surface 111A.

The upper surface 132A of the second insulating member 131B provided between the third upper surface 111F and the first upper surface 111A in a top view is located above the first upper surface 111A. The upper surface 132A is located above the third upper surface 111F. The second insulating member 131B forms the protruding portion 101M protruding upward from the first upper surface 111A.

The upper surface 132A of the second insulating member 131B provided between the fourth upper surface 111G and the first upper surface 111A in a top view is located above the first upper surface 111A. The upper surface 132A is located above the fourth upper surface 111G. The second insulating member 131B forms the protruding portion 101M protruding upward from the first upper surface 111A.

The second insulating member 131B covers a part of the first upper surface 111A extending from the first lateral surface 111C of the heat dissipation member 111. The second insulating member 131B covers a part of the upper surface 122A extending from the lateral surface 122B of the electrode member 121.

The second insulating member 131B is partially provided on the electrode member 121 in a top view. Due to the second insulating member 131B, one continuous electrode member 121 appears to be divided into a plurality of regions. In this way, a wiring pattern 101G is formed on the upper surface 101A of the wiring substrate 101.

One or more metal layers 141 are provided on the heat dissipation member 111 or the electrode member 121. The first metal layer 141A is provided on the heat dissipation member 111. The second metal layer 141B is provided on the electrode member 121. The upper surface of the one or more metal layers 141 forms a part of the region of the upper surface 101A of the wiring substrate 101. The upper surface of the insulating member 131 forms another part of the region of the upper surface 101A of the wiring substrate 101.

The upper surface of the first metal layer 141A included in the heat dissipation portion 101D can be the mounting surface of the mounting portion. The upper surface 132A of the second insulating member 131B may include the first upper surface 101A1 of the first protruding portion 101M1. The upper surface 132A of the second insulating member 131B may include the second upper surface 101A2 of the second protruding portion 101M2. The first protruding portion 101M1 and the second protruding portion 101M2 are included in the second insulating member 131B. The mounting surface of the wiring substrate 101 is included in the protruding portion 112 having the first upper surface 111A of the heat dissipation member 111 in a top view.

As the main material of the heat dissipation member 111, a metal material can be used. As the main material of the heat dissipation member 111, for example, a single-component metal, such as Cu, Ag, Al, Ni, Rh, Au, Ti, Pt, Pd, Mo, Cr, and W, or an alloy containing any of these metals can be used. The heat dissipation member 111 is preferably formed of a material with an excellent heat dissipating property. The heat dissipation member 111 can be formed containing 95 mass % or more of copper.

As the main material of the electrode member 121, a metal material can be used. As the main material of the electrode member 121, for example, a single-component metal, such as Cu, Ag, Al, Ni, Rh, Au, Ti, Pt, Pd, Mo, Cr, and W, or an alloy containing any of these metals can be used.

The insulating member 131 is formed of an insulating material. For example, polyimide can be used as the main material of the insulating member 131. Also, for example, as the main material of the insulating member 131, glass epoxy obtained by impregnating one or more glass cloths with a thermosetting insulating resin, such as an epoxy resin, and curing the thermosetting insulating resin, a liquid crystal polymer, or the like can be used. For example, film-like polyimide can be employed for the first insulating member 131A, and a resist, such as a solder resist, can be employed for the second insulating member 131B.

As the main material of the metal layer 141, a metal material, for example, Au, Ag, Cu, Pt, Ni, Pd, or an alloy containing one of these materials can be used. The metal layer 141 can be formed by performing a plating process.

### Connector 201

The connector 201 has an insertion port into which a connector cable is inserted.

### Thermistor 301

The thermistor 301 can be used as an element for measuring temperatures.

### Heat Sink 401

The heat sink 401 is a member excellent in heat dissipation performance.

### Fixing Member 501

The fixing member 501 is a member to fix a certain component to another component. An example of the fixing member 501 is a screw.

Subsequently, the light-emitting module 901 will be described.

### Light-Emitting Module 901

In the light-emitting module 901, the one or more light-emitting devices 1 are disposed on the wiring substrate 101. The one or more light-emitting devices 1 are mounted on the one or more mounting surfaces of the wiring substrate 101. The lower surface 11B of one or each of the light-emitting devices 1 is bonded to the mounting surfaces of the wiring substrate 101.

The second wiring portion 12A2 of one or each of the light-emitting devices 1 is bonded to the electrode portion 101E of the wiring substrate 101. One or each of the light-emitting devices 1 is bonded to the first electrode member 121A and the second electrode member 121B of the wiring substrate 101.

In the light-emitting device 1, the one or more light-emitting elements 20 are disposed in the package 10. The one or more light-emitting elements 20 are disposed on the first upper surface 11A of the base 11. The one or more light-emitting elements 20 are disposed in the internal space of the package 10.

The light-emitting device 1 may include the plurality of light-emitting elements 20 disposed side by side in the direction perpendicular to the first direction in a top view. Since the lower surface 101B of the wiring substrate 101 has the shape warped in the first direction, the arrangement of the plurality of light-emitting elements 20 side by side in the direction perpendicular to the first direction can suppress variations in the heat dissipation effect of heat generated from the respective light-emitting elements 20.

The one or each of the light-emitting elements 20 is disposed on the upper surface 31A of the submount 30. One or each of the submounts 30 is disposed on the first upper surface 11A of the base 11. By interposing the submount 30 between the light-emitting element 20 and the base 11, the height of the light-emitting element 20 can be adjusted. The submount 30 including the upper metal member 32B and the lower metal member 32C allows the heat dissipation property to be improved and heat generated from the light-emitting element 20 to be smoothly dissipated to the base 11.

In the light-emitting device 1, the one or more reflective members 40 are disposed in the package 10. The one or more reflective members 40 are disposed on the first upper surface 11A of the base 11. The one or more reflective members 40 are disposed in the internal space of the package 10. The lower surface 41A of one or each of the reflective members 40 is bonded to the first upper surface 11A.

The lights emitted from the one or more light-emitting elements 20 are reflected by the one or more reflective members 40. In the light-emitting device 1, the lights emitted from the one or more light-emitting elements 20 are emitted upward from the upper surface 14A of the lid body 14. The light emitted from the light-emitting element 20 is reflected by the light-reflective surface 41B and emitted from the upper surface 14A of the lid body 14.

The light-emitting device 1 may include the plurality of reflective members 40 disposed side by side in the direction perpendicular to the first direction in a top view. The one or more reflective members 40 are disposed at positions away from the one or more light-emitting elements 20 in the first direction.

In the light-emitting device 1, the one or more protective elements 50 are disposed in the package 10. The one or more protective elements 50 are disposed in the internal space of the package 10. One or each of the protective elements 50 is provided to protect the light-emitting element 20.

In the light-emitting device 1, the plurality of wiring lines 60 are provided to electrically connect the one or more light-emitting elements 20 to the package 10. The plurality of wiring lines 60 include the wiring line 60 bonded to the first wiring portion 12A1. The plurality of wiring lines 60 include the wiring line 60 bonded to the upper surface 21A of the light-emitting element 20. Further, the plurality of wiring lines 60 include the wiring line 60 bonded to the upper surface 31A of the submount 30.

In the light-emitting device 1, the optical member 70 is fixed to the package 10. The optical member 70 is bonded to the upper surface 14A of the package 10. The light emitted from the upper surface 14A of the package 10 passes through the optical member 70. The light emitted from the optical member 70 becomes light emitted from the light-emitting device 1.

The main heat source in the light-emitting device 1 is the one or more light-emitting elements 20. In an operating environment in which the light-emitting device 1 emits light, in the entire lower surface 11B of the package 10, a portion immediately below where the one or more light-emitting elements 20 are disposed relatively becomes a high temperature. The heat dissipation portion 101D of the wiring substrate 101 serves as a heat dissipation path for heat generated from the light-emitting device 1.

In the light-emitting module 901, the wiring substrate 101 is disposed on the heat sink 401. The wiring substrate 101 is disposed on the heat sink 401 such that the lower surface 101B of the wiring substrate 101 faces the upper surface of the heat sink 401. The heat generated from the light-emitting device 1 is transferred to the heat sink 401 via the heat dissipation portion 101D of the wiring substrate 101.

The wiring substrate 101 is fixed to the heat sink 401 by the fixing member 501. The wiring substrate 101 may be fixed to the heat sink 401 by a plurality of the fixing members 501. The plurality of fixing members 501 include a first fixing member 501A disposed in the first through hole 101H1 and a second fixing member 501B disposed in the second through hole 101H2.

In a case in which the fixing member 501 (the screw) is inserted into the first through hole 101H1 and the second through hole 101H2 for fixing, the warp of the lower surface 101B of the wiring substrate 101 having a shape in which the center portion is recessed with respect to both ends may cause the portion immediately below the mounting surface not to contact the heat sink 401 and the heat dissipation effect of heat generated from the light-emitting device 1 to be insufficient. The warp of the lower surface 101B of the wiring substrate 101 having a shape in which the center portion protrudes with respect to both ends allows the wiring substrate 101 to firmly contact the heat sink 401 immediately below the mounting surface. Therefore, the wiring substrate 101 having the warp of the latter shape can be said to have a more excellent heat dissipation effect.

In the light-emitting module 901, the connector 201 is disposed on the wiring substrate 101. The connector 201 is bonded to the electrode portion 101E of the wiring substrate 101. The connector 201 is electrically connected to the light-emitting device 1 via the electrode portion 101E. Using the connector 201 allows power to be supplied to the one or more light-emitting devices 1 by using connector cables.

In the light-emitting module 901, the thermistor 301 is disposed on the wiring substrate 101. The thermistor 301 is bonded to the electrode portion 101E of the wiring substrate 101. The thermistor 301 is disposed in the vicinity of the light-emitting device 1. The thermistor 301 can be used to manage a temperature of the light-emitting device 1.

The wiring substrate 101 in the embodiment is an example of a mounting substrate in which other components are mounted on the mounting surface. The component mounted on the mounting surface is a heat source device that generates heat in an operating environment. For example, a light-emitting device including a semiconductor laser element can be said to be an example of a heat source device in which heat is generated from the semiconductor laser element in an operating environment where the semiconductor laser element is caused to emit light.

Although the embodiments according to the present invention have been described above, the light-emitting module and the mounting substrate according to the present invention are not strictly limited to the light-emitting module and the mounting substrate in the embodiments. In other words, the present invention can be achieved without being limited to an outer shape or a structure of the light-emitting module or the mounting substrate disclosed by the embodiments. The present invention can be applied without requiring all the components being provided. For example, in a case in which some of the components of the light-emitting module or the mounting substrate disclosed by the embodiments are not described in the scope of claims, the degree of freedom in design by those skilled in the art, such as substitutions, omissions, shape modifications, and material changes for those components, is allowed, and then the invention described in the scope of claims being applied to those components is specified.

The light-emitting module described in the embodiments can be used in a projector. That is, the projector can be said to be one form of usage to which the present invention is applied. The present invention is not limited thereto, and can be used in various applications, such as lighting, exposure, on-vehicle headlights, head-mounted displays, backlights of other displays, and the like.

What is claimed is:

1. A manufacturing method of a mounting substrate, the manufacturing method comprising:
preparing a substrate including
a mounting portion having a mounting surface,
a first protruding portion having a first upper surface located above the mounting surface, and
a second protruding portion having a second upper surface located above the mounting surface,
the mounting surface being located between the first upper surface and the second upper surface in a top view;
disposing the substrate on a support member having a support surface such that the first upper surface and the second upper surface face the support surface; and
providing a first through hole and a second through hole from a lower surface side toward an upper surface side of the substrate at a first position and a second position between which the mounting surface is interposed in the top view, the first position and the second position not being located between the first upper surface and the mounting surface nor between the second upper surface and the mounting surface.

2. The manufacturing method according to claim 1, wherein
the preparing of the substrate includes preparing the substrate including a third protruding portion surrounding the mounting surface in the top view,
the first protruding portion is a part of the third protruding portion, and
the second protruding portion is a part of the third protruding portion.

3. The manufacturing method according to claim 1, wherein
in the top view,
the first upper surface is provided at a position away from the mounting surface in a first direction,
the first through hole is provided at a position away from the first upper surface in the first direction,
the second upper surface is provided at a position away from the mounting portion in a direction opposite to the first direction, and
the second through hole is provided at a position away from the second upper surface in the direction opposite to the first direction.

4. The manufacturing method according to claim 1, wherein
the preparing of the substrate includes preparing the substrate having
a third upper surface including the first position and a vicinity of the first position and located below the first upper surface, and
a fourth upper surface including the second position and a vicinity of the second position and located below the second upper surface, and
the providing of the first through hole and the second through hole includes providing the first through hole inside an outer edge of the third upper surface in the top view, and providing the second through hole inside an outer edge of the fourth upper surface in the top view.

5. The manufacturing method according to claim 1, wherein
the preparing the substrate includes
preparing a heat dissipation member in which a fourth protruding portion is formed on an upper surface side,
providing a first electrode member and a second electrode member at positions spaced apart from the fourth protruding portion in the top view, and
providing an insulating member between the fourth protruding portion and the first electrode member and between the fourth protruding portion and the second electrode member in the top view,
the mounting surface is included in the fourth protruding portion in the top view, and
the first protruding portion and the second protruding portion are included in the insulating member.

6. The manufacturing method according to claim 4, wherein
the preparing of the substrate includes
preparing a heat dissipation member in which a fourth protruding portion, a fifth protruding portion, and a sixth protruding portion are formed on an upper surface side,
providing a first electrode member and a second electrode member at positions spaced apart from the fourth protruding portion, the fifth protruding portion, and the sixth protruding portion in the top view, and
providing an insulating member between the fourth protruding portion and the first electrode member, between the fourth protruding portion and the second electrode member, between the fourth protruding portion and the fifth protruding portion, and between the fourth protruding portion and the sixth protruding portion in a top view,
the mounting surface is included in the fourth protruding portion in the top view,
the fifth protruding portion has the third upper surface,
the sixth protruding portion has the fourth upper surface,
the fourth protruding portion, the fifth protruding portion, and the sixth protruding portion are spaced apart from one another in the top view, and
the first protruding portion and the second protruding portion are included in the insulating member.

7. The manufacturing method according to claim 5, wherein
the providing of the first through hole and the second through hole includes providing the first through hole and the second through hole so that the fourth protruding portion is interposed between the first through hole and the second through hole in a first direction in the top view, and
the providing of the first electrode member and the second electrode member includes providing the first electrode member and the second electrode member so that the fourth protruding portion is interposed between the first electrode member and the second electrode member in a second direction intersecting with the first direction in the top view.

8. A mounting substrate comprising:
a lower surface;
a mounting portion having a mounting surface;
a first protruding portion having a first upper surface located above the mounting surface;
a second protruding portion having a second upper surface located above the mounting surface; and
an outer peripheral portion defining a first through hole and a second through hole, the outer peripheral portion being located outside the mounting portion, wherein
the mounting surface is located between the first upper surface and the second upper surface and between the first through hole and the second through hole in a top view, and
the first through hole and the second through hole are not provided between the first upper surface and the mounting surface nor between the second upper surface and the mounting surface in the top view, and
the lower surface is warped with a shape in which a point located directly below the mounting surface is located below a virtual line segment connecting a point located directly below the first upper surface and a point located directly below the second upper surface on the lower surface.

9. A light-emitting module comprising:
the mounting substrate according to claim 8; and
a light-emitting device mounted on the mounting surface.

10. The light-emitting module according to claim 9, further comprising
a heat sink on which the mounting substrate is mounted, the heat sink facing the lower surface of the mounting substrate.

11. The light-emitting module according to claim 10, further comprising:
a first fixing member that is disposed in the first through hole and fixes the mounting substrate to the heat sink; and
a second fixing member that is disposed in the second through hole and fixes the mounting substrate to the heat sink.
